(19) United States
(12) Patent Application Publication
(10) Pub. No.: US 2024/0213985 A1
(43) Pub. Date: Jun. 27, 2024

(54) Systems And Methods For Configuring Signal Paths In An Interposer Between Integrated Circuits

(71) Applicant: Altera Corporation, San Jose, CA (US)

(72) Inventors: Arch Zaliznyak, San Mateo, CA (US); Archanna Srinivasan, San Jose, CA (US); Gregory Steinke, Saratoga, CA (US)

(73) Assignee: Altera Corporation, San Jose, CA (US)

(21) Appl. No.: 18/601,665

(22) Filed: Mar. 11, 2024

(51) Int. Cl. H03K 19/173; H01L 23/00; H01L 23/538; H01L 25/10

(52) U.S. Cl. CPC H03K 19/173; H01L 23/5386; H01L 25/105; H01L 24/16; H01L 2224/16225

(57) ABSTRACT

A circuit system includes an interposer comprising conductors and switch circuits coupled to the conductors, a first integrated circuit die coupled to the interposer, and a second integrated circuit die coupled to the interposer. The first integrated circuit die comprises a primary controller circuit for configuring the switch circuits. The second integrated circuit die comprises a secondary controller circuit. The primary controller circuit configures configurable logic circuits in the second integrated circuit die by providing configuration bits to the secondary controller circuit through the interposer.

### TECHNICAL FIELD

The present disclosure relates to electronic circuit systems, and more particularly, to systems and methods for configuring signal paths in an interposer between integrated circuits coupled to the interposer.

### BACKGROUND

Configurable integrated circuits (ICs) can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that depicts an example of an integrated circuit (IC) package that includes four integrated circuit (IC) dies and an active interposer.

FIG. 2A is a diagram that depicts a side view of the integrated circuit package of FIG. 1.

FIG. 2B is a diagram that depicts an example of a switch circuit that can be used to implement one, a subset of, or each of the switch circuits in the active interposer of FIG. 1.

FIG. 3 is a diagram that illustrates an example of a configurable logic integrated circuit that can implement techniques disclosed herein.

FIG. 4A is a block diagram of a system that can be used to implement a circuit design to be programmed into a programmable logic device using design software.

FIG. 4B is a diagram that depicts an example of a programmable logic device that includes fabric dies and base dies that are connected to one another via microbumps.

FIG. 5 is a block diagram illustrating a computing system configured to implement one or more aspects of the techniques disclosed herein.

### DETAILED DESCRIPTION

In some integrated circuit packages, multiple configurable integrated circuit (IC) dies are interconnected through an interposer within a single integrated circuit package to provide higher density devices. The configurable IC dies coupled together on the interposer form a Multi-Chip Module (MCM).

In a MCM with four or more IC dies coupled together through an interposer, signal transfer latency between the IC dies through the interposer may be undesirably large. For example, in a previously known MCM having 4 IC dies, signal transfers between two of the IC dies in the MCM that are positioned diagonally from a top down view are routed through a third IC die in the MCM that is positioned between the source and destination IC dies. The signal latency accumulation through the third IC die may make the utilization of the MCM unacceptable for many circuit systems.

Therefore, it would be desirable to be able to program the couplings in an interposer in an MCM dynamically to make signal paths between two IC dies that optimize signal transfer and mode operations. It would also be desirable to be able to partially reconfigure the couplings in an interposer for a specific function in a configurable IC die.

According to some examples disclosed herein, an integrated circuit package includes multiple integrated circuit (IC) dies coupled to an active interposer. The active interposer includes partially and dynamically reconfigurable switch circuits and interconnect conductors. Two of the IC dies that are positioned diagonally from a top down view of the IC package can be coupled together through the interconnect conductors in the active interposer without routing through a third IC die, which substantially reduces signal latency between the IC dies. These couplings between the IC dies through the interposer can simplify logic placement in the IC dies by allowing circuit placement flexibility. The IC dies can be configurable IC dies that are fully configurable, partially configurable, and/or dynamically reconfigurable through the interconnect conductors in the active interposer. The dynamic and partial reconfigurability of the switch circuits in the active interposer allows protocols and modes of operation in the IC package to be changed, without needing to redesign the IC package.

According to other examples disclosed herein, one of the integrated circuit (IC) dies in the IC package includes a primary controller circuit (PCC) that configures (i.e., programs) multiple configurable IC dies in the IC package. The PCC can also configure and reconfigure the switch circuits to configure signal paths through the interconnect conductors in the active interposer. The other IC dies in the IC package can each include a secondary controller circuit (SCC). The active interposer can also include an SCC. The active interposer can include configurable couplings between the PCC and each of the SCCs in the IC package to enable system programming. The PCC and SCCs can timely control state machines in the IC dies in an optimized manner to enable various modes of operation.

The PCC can control the powering on of the IC dies in the IC package using the SCCs. The PCC can control the order in which the IC dies in the IC package are powered on by controlling the SCCs. The PCC can also configure only one of the IC dies or only a portion of one or more of the IC dies. The PCC can also configure the reconfigurable switch circuits in the active interposer to enable couplings between the IC dies. The PCC can also reconfigure and dynamically reprogram the reconfigurable switch circuits for different signal paths through the conductors to enable different operating modes. The PCC can partially reconfigure only the reconfigurable switch circuits in the active interposer that need to be reconfigured to enable different couplings and signal paths, and can maintain the configurations of the remaining switch circuits in the active interposer. The reconfigurable switch circuits can be partially and dynamically reconfigurable using configuration bit enablement, fuse bit enablement, or using firmware or software generated control bits that configure the reconfigurable switch circuits to establish the couplings and signal paths between the IC dies.

In other examples, an IC package can include IC dies that are coupled together through metal-mask-customized routing interconnect conductors in a passive interposer using metal via connection enablement. In these examples, the metal-mask-customized routing interconnect conductors in the passive interposer are specific to a package design. The routing interconnect conductors in the passive interposer can be changed for a specific design by modifying one, or only a few, new masks for one or a few layers of the routing interconnect conductors, without having to change the masks for all of the layers of the routing conductors in the interposer, which reduces development cost.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs) and programmable logic devices. As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially fewer configurable features than soft logic or no configurable features.

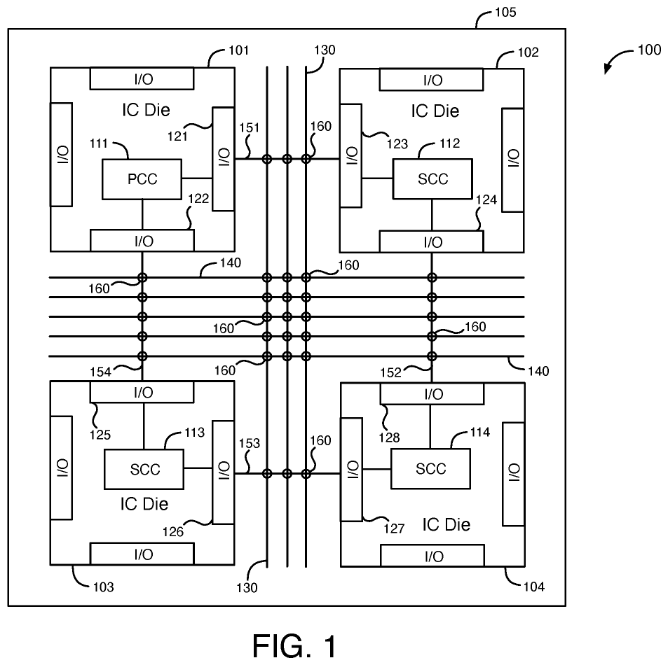

FIG. 1 is a diagram that depicts an example of an integrated circuit (IC) package 100 that includes four integrated circuit (IC) dies 101, 102, 103, and 104 and an active interposer 105. Although Figure (FIG. 1 shows 4 IC dies, in other implementations, an IC package can have any number of IC dies in accordance with the techniques disclosed herein. The IC dies 101-104 can be any types of IC dies, such as, configurable ICs (e.g., field programmable gate arrays (FPGAs) or programmable logic devices), microprocessor ICs, graphics processing unit ICs, memory ICs, application specific ICs, transceiver ICs, memory ICs, or any combination thereof. FIG. 1 shows a top down view of the IC package 100.

The active interposer 105 includes vertical routing interconnect conductors 130, horizontal routing interconnect conductors 140, and die-to-die routing interconnect conductors 151-154 that are configurable and reconfigurable to couple together any of the IC dies 101-104 in IC package 100. The vertical routing interconnect conductors 130 can, for example, be in a first conductive layer of active interposer 105, and the horizontal routing interconnect conductors 140 can, for example, be in a second conductive layer of active interposer 105. The active interposer 105 also includes reprogrammable interconnect switch circuits 160 that are configurable and reconfigurable to couple together any two crossing routing interconnect conductors. Each of the reprogrammable interconnect switch circuits 160 can, for example, include one or more multiplexer or pass gate circuits. The reprogrammable interconnect switch circuits 160 can be partially and dynamically reconfigurable using configuration bits, partial reconfiguration bits, dynamic reconfiguration bits, fuse bits, or firmware/software generated control bits to set (and later change) the couplings between the routing interconnect conductors to establish (and later change) couplings between the IC dies 101-104. The bits can, for example, be used to control the reprogrammable interconnect switch circuits 160. In a passive interposer, the interconnect switch circuits 160 can be programmed using fuse bits or programmable vias that are set during manufacturing of the interposer.

Each of the IC dies 101-104 can be coupled to two adjacent IC dies through die-to-die routing interconnect conductors. For example, input/output (I/O) circuitry 121 and 123 in IC dies 101 and 102, respectively, can be coupled together through die-to-die routing interconnect conductor 151 in active interposer 105. Input/output (I/O) circuitry 122 and 125 in IC dies 101 and 103, respectively, can be coupled together through die-to-die routing interconnect conductor 154 in active interposer 105. Input/output circuitry (I/O) 124 and 128 in IC dies 102 and 104, respectively, can be coupled together through die-to-die routing interconnect conductor 152 in active interposer 105. Input/output circuitry (I/O) 126 and 127 in IC dies 103 and 104, respectively, can be coupled together through die-to-die routing interconnect conductor 153 in active interposer 105.

In addition, two of the IC dies 101-104 that are positioned diagonally in IC package 100 from the top down view of FIG. 1 can be coupled together through the reconfigurable interconnect conductors 130, 140, and 151-154 in the active interposer 105, without routing through a third IC die. These couplings substantially reduce signal latency between the two IC dies. For example, I/O circuitry 121 and 128 in IC dies 101 and 104, respectively, can be coupled together through die-to-die interconnect conductor 151, one vertical interconnect conductor 130, one horizontal interconnect conductor 140, die-to-die interconnect conductor 152, and three interconnect switch circuits 160 in active interposer 105. As another example, I/O circuitry 124 and 125 in IC dies 102 and 103, respectively, can be coupled together through die-to-die interconnect conductor 152, one horizontal interconnect conductor 140, die-to-die interconnect conductor 154, and two interconnect switch circuits 160 in active interposer 105. As yet another example, I/O circuitry 123 and 126 in IC dies 102 and 103, respectively, can be coupled together through die-to-die interconnect conductor 151, one vertical interconnect conductor 130, die-to-die interconnect conductor 153, and two interconnect switch circuits 160 in active interposer 105. Signals can be transmitted between the IC dies 101-104 through signal transfer paths in these couplings and any other couplings created through the interconnect conductors and switch circuits 160 in active interposer 105.

Each of the IC dies 101-104 includes 4 I/O circuits, as shown in FIG. 1. In addition, each of the IC dies 101-104 includes a controller circuit. IC die 101 includes a primary controller circuit (PCC) 111. IC die 102 includes a secondary controller circuit (SCC) 112. IC die 103 includes SCC 113. IC die 104 includes SCC 114. In some examples, the PCC 111 and each of the SCCs 112-114 can be a secure device manager (SDM) that performs security functions (such as encrypting and decrypting configuration bits) for a configurable IC die.

The couplings between the IC dies 101-104 through the reconfigurable interconnect conductors 130, 140, and 151-154 in active interposer 105 can be partially or totally reconfigured to change one or more signal transfer paths between the IC dies 101-104 by reconfiguring one or more of the switch circuits 160. PCC 111 in IC die 101 can configure and reconfigure the switch circuits 160 using configuration bits, fuse bits, firmware or software bits, or other types of bits to set and reconfigure signal transfer paths through the interconnect conductors in interposer 105 for establishing couplings between IC dies 101-104. The switch circuits 160 can be controlled through metal via connections or using fuse bits during the manufacture of a passive interposer.

Reconfiguration of the switch circuits 160 enables partial reconfiguration of any subset of the die-to-die couplings between IC dies 101-104, while the other die-to-die couplings can remain unchanged to enable continued operation of the IC package. For example, an acceleration workload for a configurable IC may require different die-to-die couplings through the interposer 105, while system infrastructure (e.g., Ethernet or Peripheral Component Interconnect express (PCIe) connections) may need to stay active. Dynamic reconfiguration of the settings for the switch circuits 160 can enable different couplings from die-to-die. As mentioned above, via programming using design-specific via or metal masks can be performed for couplings between interconnect conductors in a passive interposer during manufacturing of the interposer.

In implementations in which the IC dies 101-104 are configurable IC dies, the primary controller circuit (PCC) 111 in IC die 101 can configure and partially or totally reconfigure configurable logic circuits in the configurable IC dies 101-104. In addition, the PCC 111 in IC die 101 can partially and dynamically configure and reconfigure the switch circuits 160 to change the signal transfer paths through the routing interconnect conductors 130, 140, and 151-154 in the active interposer 105. The PCC 111 can, for example, configure only one of the IC dies 102-104 or partially reconfigure only one of the IC dies 102-104. The PCC 111 can perform configuration or reconfiguration of the configurable logic circuits in the IC dies 102-104 by providing configuration bits to the SCCs 112-114 in IC dies 102-104 through the I/O circuitry, the switch circuits 160, and the reconfigurable interconnect conductors 130, 140, and/or 151-154 in the active interposer 105. PCC 111 can partially and dynamically configure and reconfigure the switch circuits 160 to provide signal transfer paths for transmitting the configuration bits from PCC 111 to SCCs 112-114 through routing interconnect conductors 130, 140, and 151-154 in interposer 105. Alternatively, PCC 111 can perform configuration or reconfiguration of the configurable logic circuits in the IC dies 102-104 by providing configuration bits to the SCCs 112-114 in IC dies 102-104, respectively, through the I/O circuitry and fixed non-programmable connections (e.g., vias) between conductors in the active interposer 105. The SCCs 112-114 can use the configuration bits received from PCC 111 to configure the configurable logic circuits in the respective IC dies 102-104.

In some implementations, the PCC 111 can dynamically reconfigure the switch circuits 160 to different patterns in order to implement various operating modes and different signal transfer paths. The PCC 111 can reconfigure only the switch circuits 160 that need to be changed to couple together the interconnect conductors needed for new signal transfer paths between IC dies, while maintaining the current configuration of the remaining switch circuits 160. The SCCs 112-114 in IC dies 102-104 work in tandem with PCC 111 to implement operating modes, including full system programmability, for IC package 100.

For example, the PCC 111 can generate and send control signals to each of the SCCs 112-114 through the I/O circuitry, selected ones of the switch circuits 160, and the interconnect conductors in interposer 105 to control the order in which the IC dies 101-104 are powered up during start-up of the IC package 100. The PCC 111 can also generate and send control signals to one or more of the SCCs 112-114 through selected ones of the switch circuits 160 and the interconnect conductors in interposer 105 to cause one or more of the IC dies 102-104, respectively, to be powered off or to remain powered off. The PCC 111 and the SCCs 112-114 can work together to control state machines across IC dies 101-104 in an optimized manner to enable various modes of operation.

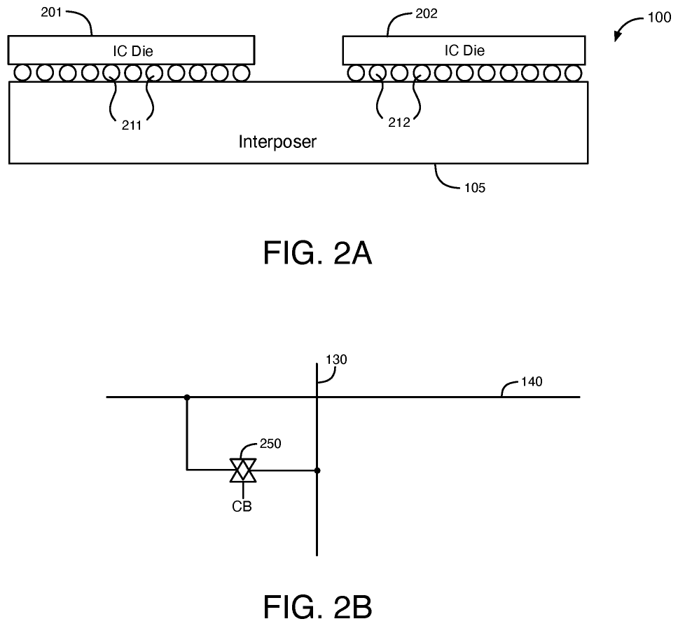

FIG. 2A is a diagram that depicts a side view of the integrated circuit package 100 of FIG. 1. In the side view of FIG. 2A, the active interposer 105 is coupled to IC die 201 through conductive microbumps 211 and to IC die 202 through conductive microbumps 212. IC dies 201 and 202 can be either IC dies 103 and 104, IC dies 104 and 102, IC dies 102 and 101, or IC dies 101 and 103, depending on which of the 4 sides of IC package 100 the view of FIG. 2A is taken from.

FIG. 2B is a diagram that depicts an example of a switch circuit 250 that can be used to implement one, a subset of, or each of the switch circuits 160 in the active interposer 105 of FIG. 1. Switch circuit 250 can, for example, include one or more pass gate circuits or two multiplexer circuits that are coupled bidirectionally. The conductive state of switch circuit 250 is controlled by one or more control bits CB. The control bits CB also control the direction of the signal that is allowed to pass through switch circuit 250. Control bits CB can configure switch circuit 250 to allow a signal to be transmitted from one of the conductors 130 to one of the conductors 140 or from the one of the conductors 140 to the one of the conductors 130 in the example of FIG. 2B.

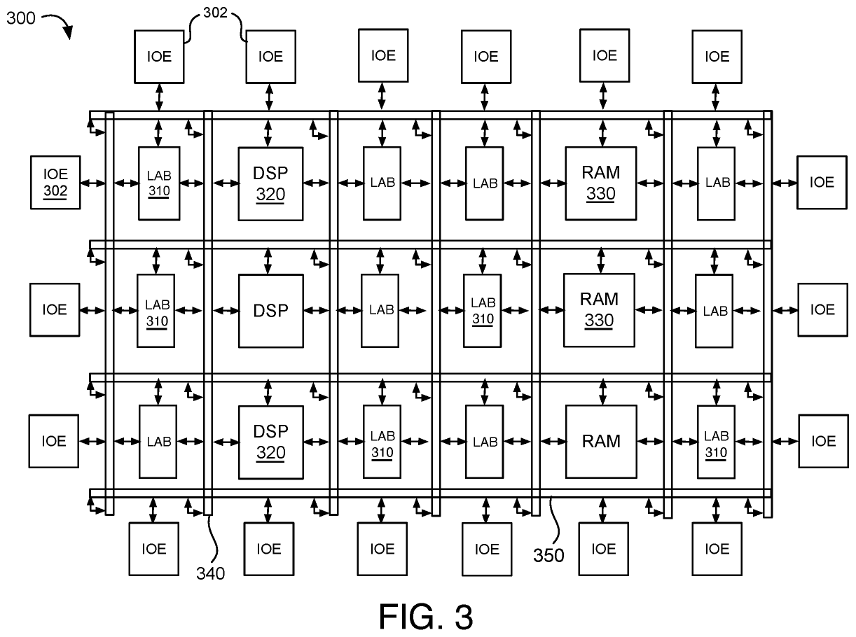

Figure (FIG.) 3 is a diagram that illustrates an example of a configurable logic IC 300 that can implement techniques disclosed herein. The IC dies disclosed herein with respect to FIGS. 1 and 2A-2B can include the architecture of configurable logic IC 300 according to some examples. As shown in FIG. 3, the configurable logic IC 300 includes a two-dimensional array of configurable functional circuit blocks, including configurable logic array blocks (LABs) 310 and other functional circuit blocks, such as random access memory (RAM) blocks 330 and digital signal processing (DSP) blocks 320. Functional blocks such as LABs 310 can include smaller configurable logic circuits (e.g., logic elements, logic blocks, or adaptive logic modules) that receive input signals and perform custom functions on the input signals to produce output signals.

In some examples, each of the IC dies 101-104 of FIG. 1 are configurable ICs that have the architecture of IC 300, and LABs 310 as shown in FIG. 3 are the configurable logic circuits in each of the IC dies 101-104. In these examples, the primary controller circuit (PCC) 111 in IC die 101 can configure and partially or totally reconfigure the LABs 310 in each of the configurable IC dies 101-104. The PCC 111 can perform configuration or reconfiguration of the LABs 310 in the IC dies 102-104 by providing configuration data bits to the SCCs 112-114 in IC dies 102-104 through the I/O circuitry, the switch circuits 160, and the reconfigurable interconnect conductors 130, 140, and/or 151-154 in the active interposer 105, as disclosed herein with respect to FIG. 1. The SCCs 112-114 configure LABs 310 in IC dies 102-104, respectively, using the configuration data bits received from PCC 111.

In addition, configurable logic IC 300 can have input/output elements (IOEs) 302 for driving signals off of configurable logic IC 300 and for receiving signals from other devices. IOEs 302 may include parallel input/output circuitry, serial data transceiver circuitry, differential receiver and transmitter circuitry, or other circuitry used to connect one integrated circuit to another integrated circuit. As shown, IOEs 302 may be located around the periphery of the chip. If desired, the configurable logic IC 300 may have IOEs 302 arranged in different ways. For example, IOEs 302 may form one or more columns, rows, or islands of input/output elements that may be located anywhere on the configurable IC 300. Input/output elements 302 can include general purpose input/output (GPIO) circuitry (e.g., on the top and bottoms edges of IC 300), high-speed input/output (HSIO) circuitry (e.g., on the left edge of IC 300), and on-package input/output (OPIOs) circuitry (e.g., on the right edge of IC 300).

The configurable logic IC 300 can also include programmable interconnect circuitry in the form of vertical routing channels 340 (i.e., interconnects formed along a vertical axis of configurable logic IC 300) and horizontal routing channels 350 (i.e., interconnects formed along a horizontal axis of configurable logic IC 300), each routing channel including at least one track to route at least one wire. One or more of the routing channels 340 and/or 350 can be part of a network-on-chip (NOC) having router circuits.

Note that other routing topologies, besides the topology of the interconnect circuitry depicted in FIG. 3, can be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Furthermore, it should be understood that embodiments disclosed herein with respect to FIG. 1 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Configurable logic IC 300 can contain programmable memory elements. Memory elements can be loaded with configuration data bits using IOEs 302. Once loaded, the memory elements each provide a corresponding static control signal that controls the operation of an associated configurable functional block (e.g., LABs 310, DSP blocks 320, RAM blocks 330, or IOEs 302). The configuration data bits can set the functions of the configurable functional circuit blocks (i.e., soft logic) in IC 300.

In a typical scenario, the outputs of the loaded memory elements are applied to the gates of field-effect transistors in a functional block to turn certain transistors on or off and thereby configure the logic in the functional block including the routing paths. Programmable logic circuit elements that are controlled in this way include parts of multiplexers (e.g., multiplexers used for forming routing paths in interconnect circuits), look-up tables, logic arrays, AND, OR, NAND, and NOR logic gates, pass gates, etc.

The memory elements can use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data bits during programming, the memory elements are sometimes referred to as configuration memory or programmable memory elements.

The memory elements can be organized in a configuration memory array consisting of rows and columns. A data register that spans across all columns and an address register that spans across all rows may receive configuration data bits. The configuration data bits can be shifted onto the data register. When the appropriate address register is asserted, the data register writes the configuration data bits to the configuration memory bits of the row that was designated by the address register.

Configurable integrated circuit 300 can include configuration memory that is organized in sectors, whereby a sector can include the configuration bits that specify the function and/or interconnections of the subcomponents and wires in or crossing that sector. Each sector can include separate data and address registers.

The configurable IC of FIG. 3 is merely one example of an IC that can include embodiments disclosed herein. The embodiments disclosed herein may be incorporated into any suitable integrated circuit or system. For example, the embodiments disclosed herein can be incorporated into numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein may be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

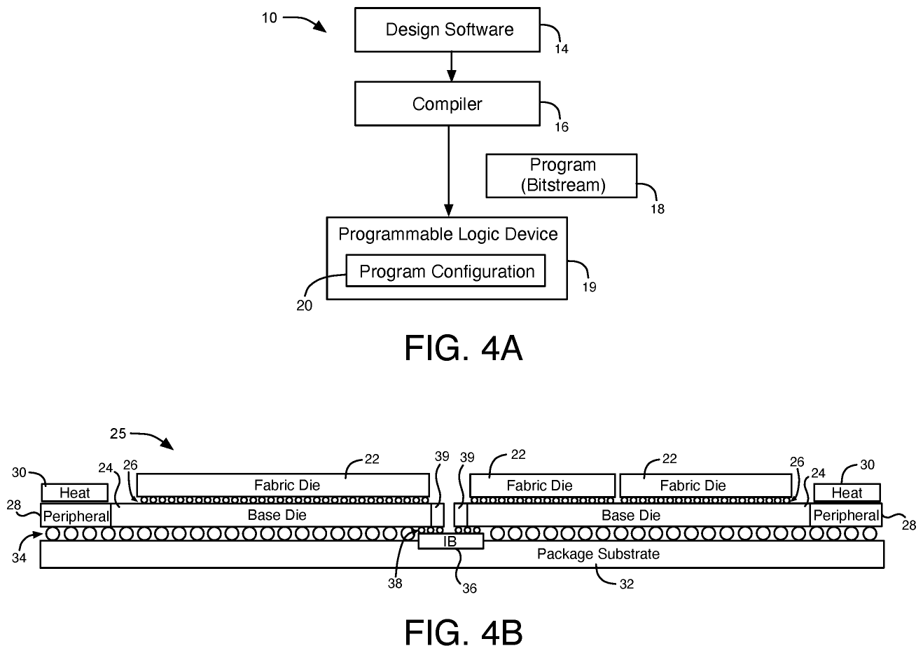

FIG. 4A illustrates a block diagram of a system 10 that can be used to implement a circuit design to be programmed onto a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized tasks.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 4B, but many others can be used, and it should be understood that this disclosure is intended to encompass any suitable programmable logic device where programmable logic fabric and fabric support circuitry are at least partially separated on different integrated circuit die.

FIG. 4B is a diagram that depicts an example of the programmable logic device 25 that includes three fabric die 22 and two base die 24 that are connected to one another via microbumps 26. In the example of FIG. 4B, at least some of the programmable logic fabric of the programmable logic device 25 is in the three fabric die 22, and at least some of the fabric support circuitry that operates the programmable logic fabric is in the two base die 24. For example, some of the circuitry of configurable IC 300 shown in FIG. 3 (e.g., LABs 310, DSP 320, RAM 330) can be located in the fabric die 22 and some of the circuitry of IC 300 (e.g., input/output elements 302) can be located in the base die 24.

Although the fabric die 22 and base die 24 appear in a one-to-one relationship or a two-to-one relationship in FIG. 4B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 25. The heat spreaders 30 can appear above, as pictured, and/or below the package (e.g., as a double-sided heat sink). The base die 24 can attach to a package substrate 32 via conductive bumps 34. In the example of FIG. 4B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 25 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

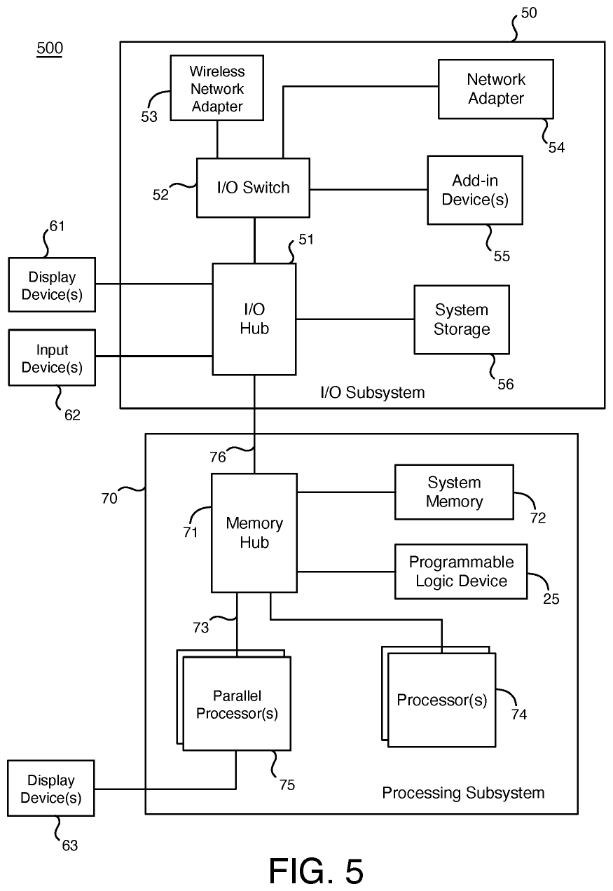

FIG. 5 is a block diagram illustrating a computing system 500 configured to implement one or more aspects of the embodiments described herein. The computing system 500 includes a processing subsystem 70 having one or more processor(s) 74, a system memory 72, and a programmable logic device 25 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 500 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 500. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 500 can include other components not shown in FIG. 5, including other port connections, optical storage drives, video capture devices, and the like, that can also be connected to the I/O hub 51. Communication paths interconnecting the various components in FIG. 5 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 500 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 500 can be integrated into a single package to form a system in package (SIP) configuration. In one embodiment, at least a portion of the components of the computing system 500 can be integrated into a multi-chip module (MCM), which can be interconnected with other multi-chip modules into a modular computing system.

The computing system 500 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 500. For example, any number of add-in cards or peripherals can be supported, or some components can be eliminated. Furthermore, some architectures can use different terminology for components similar to those illustrated in FIG. 5. For example, the memory hub 71 can be referred to as a Northbridge in some architectures, while the I/O hub 51 can be referred to as a Southbridge.

Additional examples are now described. Example 1 is a circuit system comprising an interposer comprising conductors and switch circuits coupled to the conductors; a first integrated circuit die coupled to the interposer, wherein the first integrated circuit die comprises a primary controller circuit for configuring the switch circuits; and a second integrated circuit die coupled to the interposer, wherein the second integrated circuit die comprises a first secondary controller circuit, and wherein the primary controller circuit configures a first configurable logic circuit in the second integrated circuit die by providing first configuration bits to the first secondary controller circuit through the interposer.

In Example 2, the circuit system of Example 1 further comprises: a third integrated circuit die coupled to the interposer, wherein the third integrated circuit die comprises a second secondary controller circuit, and wherein the primary controller circuit configures a second configurable logic circuit in the third integrated circuit die by providing second configuration bits to the second secondary controller circuit through the interposer.

In Example 3, the circuit system of Example 2 further comprises: a fourth integrated circuit die coupled to the interposer, wherein the fourth integrated circuit die comprises a third secondary controller circuit, and wherein the primary controller circuit configures a third configurable logic circuit in the fourth integrated circuit die by providing third configuration bits to the third secondary controller circuit through the interposer.

In Example 4, the circuit system of Example 3 may optionally include, wherein the primary controller circuit provides control signals to the first secondary controller circuit, the second secondary controller circuit, and the third secondary controller circuit through the switch circuits and the conductors to control an order in which the second, the third, and the fourth integrated circuit dies are powered up.

In Example 5, the circuit system of any one of Examples 1-4 may optionally include, wherein the primary controller circuit reconfigures the first configurable logic circuit in the second integrated circuit die by providing second configuration bits to the first secondary controller circuit through the interposer.

In Example 6, the circuit system of any one of Examples 1-5 may optionally include, wherein the primary controller circuit configures the switch circuits to couple together a first subset of the conductors, and wherein the primary controller circuit reconfigures the switch circuits to couple together a second subset of the conductors.

In Example 7, the circuit system of any one of Examples 1-6 may optionally include, wherein the primary controller circuit configures a first subset of the switch circuits to couple together a subset of the conductors, while maintaining a configuration of a second subset of the switch circuits.

In Example 8, the circuit system of any one of Examples 1-7 may optionally include, wherein the first secondary controller circuit configures the first configurable logic circuit and a second configurable logic circuit in the second integrated circuit die using the first configuration bits.

In Example 9, the circuit system of any one of Examples 1-8 may optionally include, wherein the primary controller circuit reconfigures the switch circuits to provide paths for transmitting signals between the first integrated circuit die and the second integrated circuit die in order to implement operating modes.

In Example 10, the circuit system of any one of Examples 1-9 may optionally include, wherein the primary controller circuit configures the switch circuits using at least one of second configuration bits, partial reconfiguration bits, dynamic reconfiguration bits, fuse bits, firmware bits, or software bits to set couplings between the conductors.

Example 11 is a method for configuring first configurable logic circuits, the method comprising configuring first switch circuits in an interposer to provide a first signal path for transmitting first signals through the first switch circuits and first conductors in the interposer using a primary controller circuit in a first integrated circuit die coupled to the interposer; providing first configuration bits from the primary controller circuit through the interposer to a first secondary controller circuit in a second integrated circuit die coupled to the interposer; and configuring the first configurable logic circuits in the second integrated circuit die with the first configuration bits using the first secondary controller circuit.

In Example 12, the method of Example 11 further comprises: configuring second switch circuits in the interposer to provide a second signal path for transmitting second signals through the second switch circuits and second conductors in the interposer using the primary controller circuit.

In Example 13, the method of any one of Examples 11-12 further comprises: providing second configuration bits from the primary controller circuit through the interposer to a second secondary controller circuit in a third integrated circuit die coupled to the interposer; and configuring second configurable logic circuits in the third integrated circuit die with the second configuration bits using the second secondary controller circuit.

In Example 14, the method of Example 13 further comprises: providing control signals from the primary controller circuit to the first secondary controller circuit and to the second secondary controller circuit through third switch circuits in the interposer and third conductors in the interposer to control an order in which the second and the third integrated circuit dies are powered up.

In Example 15, the method of any one of Examples 11-14 further comprises: configuring second switch circuits in the interposer using the primary controller circuit to provide second signal paths for transmitting second signals through the interposer between the first integrated circuit die and the second integrated circuit die in order to implement operating modes.

In Example 16, the method of any one of Examples 11-15 may optionally include, wherein the primary controller circuit configures the first switch circuits to couple together the first conductors, while maintaining a configuration of second switch circuits in the interposer.

Example 17 is a non-transitory computer readable storage medium comprising computer readable instructions stored thereon for causing a circuit system to: configure first switch circuits in an interposer to provide a first signal path for transmitting first signals through the first switch circuits and first conductors in the interposer using a primary controller circuit in a first integrated circuit die coupled to the interposer; provide first configuration bits from the primary controller circuit through the interposer to a first secondary controller circuit in a second integrated circuit die coupled to the interposer; and configure the first configurable logic circuits in the second.

In Example 18, the non-transitory computer readable storage medium of Example 18 may optionally include, wherein the computer readable instructions further cause the primary controller circuit to provide second configuration bits to a second secondary controller circuit through a second signal path for configuring second configurable logic circuits in a third integrated circuit coupled to the interposer.

In Example 19, the non-transitory computer readable storage medium of any one of Examples 17-18 may optionally include, wherein the computer readable instructions further cause the primary controller circuit to configure the first switch circuits using any one of second configuration bits, partial reconfiguration bits, dynamic reconfiguration bits, fuse bits, firmware bits, or software bits to implement the first signal path.

In Example 20, the non-transitory computer readable storage medium of any one of Examples 17-19 may optionally include, wherein the computer readable instructions further cause the primary controller circuit to control an order in which the second integrated circuit die and a third integrated circuit die in the circuit system are powered up by providing control signals through the interposer.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A circuit system comprising:
an interposer comprising conductors and switch circuits coupled to the conductors;
a first integrated circuit die coupled to the interposer, wherein the first integrated circuit die comprises a primary controller circuit for configuring the switch circuits; and
a second integrated circuit die coupled to the interposer, wherein the second integrated circuit die comprises a first secondary controller circuit, and wherein the primary controller circuit configures a first configurable logic circuit in the second integrated circuit die by providing first configuration bits to the first secondary controller circuit through the interposer.

2. The circuit system of claim 1 further comprising:
a third integrated circuit die coupled to the interposer, wherein the third integrated circuit die comprises a second secondary controller circuit, and wherein the primary controller circuit configures a second configurable logic circuit in the third integrated circuit die by providing second configuration bits to the second secondary controller circuit through interposer.

3. The circuit system of claim 2 further comprising:
a fourth integrated circuit die coupled to the interposer, wherein the fourth integrated circuit die comprises a third secondary controller circuit, and wherein the primary controller circuit configures a third configurable logic circuit in the fourth integrated circuit die by providing third configuration bits to the third secondary controller circuit through the interposer.

4. The circuit system of claim 3, wherein the primary controller circuit provides control signals to the first secondary controller circuit, the second secondary controller circuit, and the third secondary controller circuit through the switch circuits and the conductors to control an order in which the second, the third, and the fourth integrated circuit dies are powered up.

5. The circuit system of claim 1, wherein the primary controller circuit reconfigures the first configurable logic circuit in the second integrated circuit die by providing second configuration bits to the first secondary controller circuit through the interposer.

6. The circuit system of claim 1, wherein the primary controller circuit configures the switch circuits to couple together a first subset of the conductors, and wherein the primary controller circuit reconfigures the switch circuits to couple together a second subset of the conductors.

7. The circuit system of claim 1, wherein the primary controller circuit configures a first subset of the switch circuits to couple together a subset of the conductors, while maintaining a configuration of a second subset of the switch circuits.

8. The circuit system of claim 1, wherein the first secondary controller circuit configures the first configurable logic circuit and a second configurable logic circuit in the second integrated circuit die using the first configuration bits.

9. The circuit system of claim 1, wherein the primary controller circuit reconfigures the switch circuits to provide paths for transmitting signals between the first integrated circuit die and the second integrated circuit die in order to implement operating modes.

10. The circuit system of claim 1, wherein the primary controller circuit configures the switch circuits using at least one of second configuration bits, partial reconfiguration bits, dynamic reconfiguration bits, fuse bits, firmware bits, or software bits to set couplings between the conductors.

11. A method for configuring first configurable logic circuits, the method comprising:
configuring first switch circuits in an interposer to provide a first signal path for transmitting a first signal through the first switch circuits and first conductors in the interposer using a primary controller circuit in a first integrated circuit die coupled to the interposer;
providing first configuration bits from the primary controller circuit through the interposer to a first secondary controller circuit in a second integrated circuit die coupled to the interposer; and
configuring the first configurable logic circuits in the second integrated circuit die with the first configuration bits using the first secondary controller circuit.

12. The method of claim 11 further comprising:
configuring second switch circuits in the interposer to provide a second signal path for transmitting a second signal through the second switch circuits and second conductors in the interposer using the primary controller circuit.

13. The method of claim 12 further comprising:
providing second configuration bits from the primary controller circuit through the interposer to a second secondary controller circuit in a third integrated circuit die coupled to the interposer; and
configuring second configurable logic circuits in the third integrated circuit die with the second configuration bits using the second secondary controller circuit.

14. The method of claim 13 further comprising:
providing control signals from the primary controller circuit to the first secondary controller circuit and to the second secondary controller circuit through third switch circuits in the interposer and third conductors in the interposer to control an order in which the second and the third integrated circuit dies are powered up.

15. The method of claim 11 further comprising:
configuring second switch circuits in the interposer using the primary controller circuit to provide second signal paths for transmitting second signals through the interposer between the first integrated circuit die and the second integrated circuit die in order to implement operating modes.

16. The method of claim 11, wherein the primary controller circuit configures the first switch circuits to couple together the first conductors, while maintaining a configuration of second switch circuits in the interposer.

17. A non-transitory computer readable storage medium comprising computer readable instructions stored thereon for causing a circuit system to:
configure first switch circuits in an interposer to provide a first signal path for transmitting a first signal through the first switch circuits and first conductors in the interposer using a primary controller circuit in a first integrated circuit die coupled to the interposer;
provide first configuration bits from the primary controller circuit through the interposer to a first secondary controller circuit in a second integrated circuit die coupled to the interposer; and
configure first configurable logic circuits in the second integrated circuit die with the first configuration bits using the first secondary controller circuit.

18. The non-transitory computer readable storage medium of claim 17, wherein the computer readable instructions further cause the primary controller circuit to provide second configuration bits to a second secondary controller circuit through the interposer for configuring second configurable logic circuits in a third integrated circuit coupled to the interposer.

19. The non-transitory computer readable storage medium of claim 17, wherein the computer readable instructions further cause the primary controller circuit to configure the first switch circuits using any one of second configuration bits, partial reconfiguration bits, dynamic reconfiguration bits, fuse bits, firmware bits, or software bits to implement the first signal path.

20. The non-transitory computer readable storage medium of claim 17, wherein the computer readable instructions further cause the primary controller circuit to control an order in which the second integrated circuit die and a third integrated circuit die in the circuit system are powered up by providing control signals through the interposer to the second and the third integrated circuit dies.
